(19) United States
(12) Patent Application Publication
(10) Pub. No.: US 2005/0191409 A1
(43) Pub. Date: Sep. 1, 2005

(54) Ion beam monitoring arrangement

(76) Inventors: Adrian Murrell, West Sussex (GB); Bernard F. Harrison, West Sussex (GB); Peter Edwards, West Sussex (GB); Peter Kindersley, West Sussex (GB); Robert Mitchell, West Sussex (GB); Theodore Smick, Essex, MA (US); Geoffrey Ryding, Manchester, MA (US); Marvin Farley, Ipswich, MA (US); Takao Sakase, Rowley, MA (US)

Correspondence Address: Robert W. Mulcahy;Applied Materials, Inc., Box 450A, Santa Clara, CA, 95052, US

(21) Appl. No.: 11/029,004

(22) Filed: Jan. 5, 2005

(30) Foreign Application Priority Data
Jan. 6, 2004 (GB) 0400185.5

(51) Int. Cl. C23C 14/00; B05D 1/00; C23C 16/00

(52) U.S. Cl. 427/8; 427/523; 118/720; 118/712

(57) ABSTRACT

This invention relates to an ion beam monitoring arrangement for use in an ion implanter where it is desirable to monitor the flux and/or a cross-sectional profile of the ion beam used for implantation. It is often desirable to measure the flux and/or cross-sectional profile of an ion beam in an ion implanter in order to improve control of ion implantation of a semiconductor wafer or similar. The present invention describes adapting the wafer holder to allow such beam profiling to be performed. The substrate holder may be used progressively to occlude the ion beam from a downstream flux monitor or a flux monitor may be located on the wafer holder that is provided with a slit entrance aperture.

### FIELD OF THE INVENTION

This invention relates to an ion beam monitoring arrangement for use in an ion implanter where it is desirable to monitor the flux and/or a cross-sectional profile of the ion beam used for implantation. This invention also relates to an ion implanter process chamber and an ion implanter including such an ion beam monitoring arrangement, and to a method of monitoring an ion beam in an ion implanter.

### BACKGROUND OF THE INVENTION

Ion implanters are well known and generally conform to a common design as follows. An ion source produces a mixed beam of ions from a precursor gas or the like. Only ions of a particular species are usually required for implantation in a substrate, for example a particular dopant for implantation in a semiconductor wafer. The required ions are selected from the mixed ion beam using a mass-analysing magnet in association with a mass-resolving slit. Hence, an ion beam containing almost exclusively the required ion species emerges from the mass-resolving slit to be transported to a process chamber where the ion beam is incident on a substrate held in place in the ion beam path by a substrate holder.

It is often desirable to measure the flux and/or cross-sectional profile of an ion beam in an ion implanter in order to improve control of the implantation process. One example where such a desire exists is in ion implanters where the ion beam size is smaller than the substrate to be implanted. In order to ensure ion implantation across the whole of the substrate, the ion beam and substrate are moved relative to one another such that the ion beam scans the entire substrate surface. This may be achieved by (a) deflecting the ion beam to scan across the substrate that is held in a fixed position, (b) mechanically moving the substrate whilst keeping the ion beam path fixed or (c) a combination of deflecting the ion beam and moving the substrate. Generally, relative motion is effected such that the ion beam traces a raster pattern on the substrate.

To achieve uniform implantation, the ion beam flux and cross sectional profile in at least one dimension needs to be known and also need to be checked periodically to allow any variations to be corrected. For example, uniform doping requires adequate overlap between adjacent scan lines. Put another way, if the spacing between adjacent scan lines of the raster scan is too large (with respect to the ion beam width and profile), ‘striping’ of the substrate will result with periodic bands of increased and decreased doping levels. Dose uniformity problems in a raster-scanned ion implanter are discussed in WO03/088299.

Our co-pending U.S. patent application Ser. No. 10/119290 describes an ion implanter of the general design described above. A single substrate is held in a moveable substrate holder. While some steering of the ion beam is possible, the implanter is operated such that ion beam follows a fixed path during implantation. Instead, the substrate holder is moved along two orthogonal axes to cause the ion beam to scan over the substrate following a raster pattern. The substrate holder is provided with a Faraday with an entrance aperture of 1 cm² that is used to sample the ion beam flux. Sampling at different positions within the ion beam is performed by moving the Faraday using the substrate holder. Accordingly, the ion beam flux can be sampled at an array of locations corresponding to the two axes of translation of the substrate holder and a two-dimensional profile of the ion beam flux can be accumulated.

This arrangement suffers from some disadvantages in certain applications. Firstly, it requires a Faraday to be placed on the substrate holder. This adds weight to the substrate holder that is supported in a cantilever fashion. Moreover, many ion implanters comprise a beamstop placed downstream of the substrate holder that includes a Faraday thereby leading to duplication of detectors with associated complexity and expense. Secondly, the entrance aperture of the Faraday is much smaller than the ion beam. As a result, the aperture can collect only a small signal leading to noisy data or long acquisition times. The total data collection is very slow as, in addition to lengthy acquisition times needed to produce an acceptable signal to noise ratio, the ion beam must be sampled at many points over a two-dimensional grid to provide a profile. Acquisition times may be reduced if a profile in only one dimension is required as only a single line of data points is required. However, careful alignment with the ion beam must be performed for the aperture to pass through the centre of the ion beam, otherwise the full width of the ion beam will not be measured.

### SUMMARY OF THE INVENTION

According to a first aspect, the present invention resides in a method of measuring an ion beam flux profile in an ion implanter operable to generate an ion beam along an ion beam path for implanting in a substrate held at a target position by a substrate support, the ion implanter comprising an ion beam flux detector located downstream of the target position and a shield provided by the substrate support for shielding the detector from the ion beam when the shield is located in the ion beam path, the method comprising the steps of:

(a) causing a first relative motion between the substrate support and the ion beam such that the shield occludes the ion beam by a progressively changing amount;

(b) measuring the ion beam flux with the detector during said first relative motion; and

(c) determining the ion beam flux profile in a first direction by using changes in the measured ion beam flux.

By “profile”, it will be understood that a cross-sectional profile in at least one dimension is intended. Most commonly, measuring the ion beam flux will comprise measuring a current produced by ions incident on a detector.

The arrangement described above is beneficial as it allows the cross-sectional profile of the ion beam to be measured using a Faraday or similar already provided as a beamstop. By occluding the ion beam by a progressively changing amount, i.e. moving the shield into the ion beam to cause progressive occlusion or moving the shield out of the ion beam to progressively uncover the ion beam, successive measurements may be taken and the ion beam profile calculated from changes in the successive measurements. This calculation may correspond to taking simple differences or may correspond to finding a derivative of the successive measurements.

Using the substrate support to provide the shield is particularly advantageous as it removes the need for providing a further component to the ion implanter. It also enjoys the benefit that the ion beam is occluded at a position at or close to the target position such that the ion beam profile at or close to the target position is obtained.

The measurements may be collected during the first relative motion such that the ion beam flux is measured for set time intervals before being dumped into bins. Although measured as a function of time, each measurement corresponds to a different position within the ion beam and so provides a spatial profile rather than a temporal profile. Alternatively, the first relative motion may comprise a number of successive movements between positions with measurements being collected whilst stationary at each position.

Optionally, the ion implanter comprises a further said shield provided by the substrate support and the method further comprises the steps of: causing a second relative motion between the substrate support and the ion beam such that the further shield occludes the ion beam by a progressively changing amount; measuring the ion beam flux with the detector during said second relative motion; and determining the ion beam flux profile in a second direction by using changes in the measured ion beam flux. The shield and further shield may be entirely separate or they may be different parts of the same structure.

Conveniently, this allows cross-sectional profiles to be collected in two directions. Preferably, the first and second directions are substantially orthogonal thereby providing cross-sectional profiles in two orthogonal directions. The shield and/or further shield may extend across the full extent of the ion beam. Alternatively, the shield and/or further shield may extend across only part of the ion beam.

From a second aspect the present invention resides in a method of measuring an ion beam flux profile in an ion implanter operable to generate an ion beam along an ion beam path for implanting in a substrate held at a target position by a substrate support, the ion implanter comprising an ion beam flux detector located downstream of the target position and a slot aperture provided in the substrate support for letting only a portion of the ion beam propagate to the detector when the aperture is located in the ion beam path, the method comprising the steps of: (a) causing a first relative motion between the substrate support and the ion beam such that the ion beam scans across the aperture; (b) using the detector to take measurements of the ion beam flux during the first relative motion through the ion beam; and (c) determining an ion beam flux profile from the ion beam flux measurements.

This arrangement allows successive portions of the ion beam flux to be measured and the ion beam profile determined therefrom. It requires only a minor adaptation of the substrate support and may use the Faraday that is often already present at the beamstop.

From a third aspect, the present invention resides in a method of measuring an ion beam flux profile in an ion implanter operable to generate an ion beam along an ion beam path for implanting in a substrate held at a target position by a substrate support, the substrate support providing a first elongate slot ion beam flux detector, the method comprising the steps of:

causing a first relative motion between the substrate support and the ion beam such that the ion beam scans across the first detector;

using the first detector to take measurements of the ion beam flux during the first relative motion through the ion beam; and

determining a first ion beam flux profile from the ion beam flux measurements.

The term “elongate slot ion beam flux detector” is intended to encompass detectors that measure ion beam flux over an elongate area. They may have an elongate active detecting area or the active detecting area may sit behind an elongate aperture.

Measuring the ion beam flux along using an elongate slot detector improves statistics as it simply provides an average flux along the elongate direction rather than discretely sampling the flux at a plurality of point-like positions. For example, the detector could measure the ion beam flux along a line spanning the ion beam. Then, the total flux for successive strips across the ion beam could be measured to yield a cross-sectional profile.

From a fourth aspect, the present invention resides in a method of measuring an ion beam path, comprising: performing the method of measuring an ion beam described above such that steps (a) and (b) are performed at a first position along the assumed ion beam path and step (c) is performed to determine a first ion beam flux profile at the first position; repeating steps (a) and (b) at a second position spaced along the assumed ion beam path from the first position and step (c) to determine a second ion beam flux profile at the second position; identifying a common feature in the first and second flux profiles; determining the positions of the common feature in the first and second flux profiles; and inferring the ion beam path from the positions so determined.

Such a method allows the path of the ion beam to be determined. This is useful, for example, where control of the angle of incidence between substrate and ion beam is required. The common feature used for determining the ion beam path may be the centroid of the ion beam, for example. More than the common feature may be used to determine the ion beam path. In fact, the entire profile of the ion beam may be mapped between the first and second positions.

Variation in the angle of incidence of the ion beam about the Y axis is particularly important for control during high tilt implants. This corresponds to rotating the support arm to cause a high-tilt of the wafer (and hence larger angle of incidence of the ion beam) so that dopants can be implanted underneath high aspect ratio structures. (e.g. source extension halo implants). Any variation from a required beam angle about the Y-axis will change the extent to which the ions penetrate the structure, thereby changing the performance characteristics of the device being implanted.

From a fifth aspect, the present invention resides in an ion beam monitoring arrangement for use in an ion implanter operable to generate an ion beam along an ion beam path for implanting in a substrate held at a target position, the ion beam monitoring arrangement comprising:

a substrate support arranged to hold the substrate at the target position;

a detector located in the ion beam path downstream of the target position and operable to take measurements of the ion beam flux incident on the detector;

a shield provided by the substrate support in a position to occlude the ion beam from the detector by a progressively changing amount during a first relative motion between the substrate support and the ion beam; and

processing means operable to determine an ion beam flux profile in a first direction by using changes in the ion beam flux measurements.

Such an arrangement may be used with the method described above and so enjoys the same benefits.

Optionally, the substrate support comprises a support arm with an edge for occluding the ion beam. Another arrangement includes a substrate support including a chuck with a first edge for occluding the ion beam during the first relative motion. Optionally, the substrate support is rotatable about its longitudinal axis and the shield is located on the chuck to be eccentric with respect to the longitudinal axis. Such an arrangement is beneficial as the position of the shield along the ion beam path can be changed by rotating the substrate support. Thus, ion beam flux profiles may be taken at two or more positions along the assumed ion beam path and the exact path of the ion beam determined.

The edge is preferably straight, although other shapes are possible. Where a straight edge is employed, the edge may advantageously extend substantially perpendicular to the direction of the first relative motion. This is advantageous as it simplifies the mathematical treatment required to obtain the profile. For example, where a curved edge is employed, the shape of the curve must be known to allow a deconvolution of that shape from the ion beam flux measurements. Optionally, the substrate support comprises a chuck with a first face for receiving a substrate and a second, opposed face having the shield projecting therefrom. The shield may have edges to provide the shield and further shield.

From a sixth aspect, the present invention resides in an ion beam monitoring arrangement for use in an ion implanter operable to generate an ion beam along an ion beam path for implanting in a substrate held at a target position, the ion beam monitoring arrangement comprising: a substrate support arranged to hold the substrate at the target position; a detector located in the ion beam path downstream of the target position and operable to take measurements of the ion beam flux incident thereon; a slot aperture provided in the substrate support in a position to allow portions of the ion beam to propagate to the detector during a first relative motion between the substrate support and the ion beam; and processing means operable to determine a first ion beam flux profile from the ion beam flux measurements. From a seventh aspect, the present invention resides in an ion beam monitoring arrangement for use in an ion implanter operable to generate an ion beam along an ion beam path for implanting in a substrate held at a target position, the ion beam monitoring arrangement comprising:

a substrate support arranged to hold the substrate at the target position; a first elongate slot ion beam flux detector provided by the substrate support operable to take measurements of the ion beam flux incident thereon during a first relative motion between the substrate support and the ion beam; and

processing means operable to determine a first ion beam flux profile from the ion beam flux measurements.

Such an arrangement may be used with the method described above and so enjoys the same benefits.

Optionally, the first detector may comprise a recess detecting element located behind a deep recess. Advantageously, this limits the acceptance angle of the detector and allows angular measurements of the ion beam profile to be collected. For example, the detector may be tilted with respect to the ion beam to determine the exact angle of propagation of the ion beam along the ion beam path.

Optionally, the first detector comprises an elongate array of discrete detecting elements, being operable to take measurements of the ion beam flux incident thereon during the first relative motion, and the processing means are operable to determine an ion beam flux profile by summing concurrent ion beam flux measurements taken by detecting elements within the array and to determine a further ion beam flux profile from the ion beam flux measurements taken by a detecting element.

The use of discrete detecting elements allows the determination of cross-sectional profiles in two directions at the same time. Preferably, the detecting elements are disposed in two adjacent, parallel lines in an alternating zig-zag pattern. This allows an array of detectors whose active detecting area may extend across a full width of the ion beam, as any dead areas (that may otherwise separate detecting elements disposed along a single line) to be overlapped across the two lines.

From an eighth aspect, the present invention resides in an ion beam monitoring arrangement for use in an ion implanter operable to generate an ion beam along an ion beam path for implanting in a substrate, the ion beam monitoring arrangement comprising (a) first measurement means operable to measure a first ion beam flux profile at a first position along the assumed path of the ion beam; (b) second measurement means operable to measure a second ion beam profile at a second position spaced along the assumed path of the ion beam from the first position; and (c) processing means operable to identify a common feature in the first and second flux profiles, to determine the positions of the common feature in the first and second flux profiles and to infer the ion beam path from the position so determined.

The present invention also extends to an ion implanter process chamber including an ion beam monitoring arrangement as described above and to an ion implanter including an ion beam monitoring arrangement as described above.

Other preferred, but optional, features are set out in the appended claims.

### BRIEF DESCRIPTION OF THE DRAWINGS

Examples of the invention will now be described with reference to the accompanying drawings, in which:

FIG. 1a shows a schematic side view of an ion implanter in which a substrate is mounted on a substrate support;

FIG. 1b shows a part section along line AA of FIG. 1a;

FIGS. 2a to 2c are schematic representations of three scanning patterns performed by the ion implanter of FIGS. 1a and 1b;

FIG. 3 is a simplified representation showing partial occlusion of an ion beam prior to the ion beam striking a Faraday beamstop;

FIG. 4 is a simplified representation showing how the support arm is used to occlude the ion beam in a first embodiment of the present invention;

FIG. 5 is a simplified representation showing how one of two orthogonal screens provided on a substrate holder attached to a support arm of the substrate support is used to occlude the ion beam in a second embodiment of the present invention;

FIG. 6 is a simplified representation showing how a shield projecting from a wafer holder of the substrate support is used to occlude the ion beam in a third embodiment of the present invention;

FIG. 7 is a simplified representation showing a shield projecting from a wafer holder provided with an aperture that allows a slice of the ion beam flux therethrough;

FIG. 8 is a simplified representation showing a scanning support arm including a Faraday with a slot entrance aperture;

FIG. 9 is a simplified representation showing a substrate holder having a pair of Faradays with orthogonally-disposed slot entrance apertures;

FIG. 10 is a simplified representation showing a pair of Faradays with orthogonally-disposed slot entrance apertures provided in a shield that projects from the wafer holder;

FIG. 11 is a simplified representation showing a substrate holder having an array of Faradays disposed in zig-zag formation;

FIGS. 12a and 12b show a shield arrangement akin to that of FIG. 6 being used to obtain an ion beam flux profile at two positions along the ion beam path; and

FIGS. 13a and 13b are two perspective views of an end piece of a substrate support that includes a pair of Faraday detectors; and

FIG. 13c is a section through line AA of FIG. 13a

### DESCRIPTION OF THE PREFERRED EMBODIMENTS

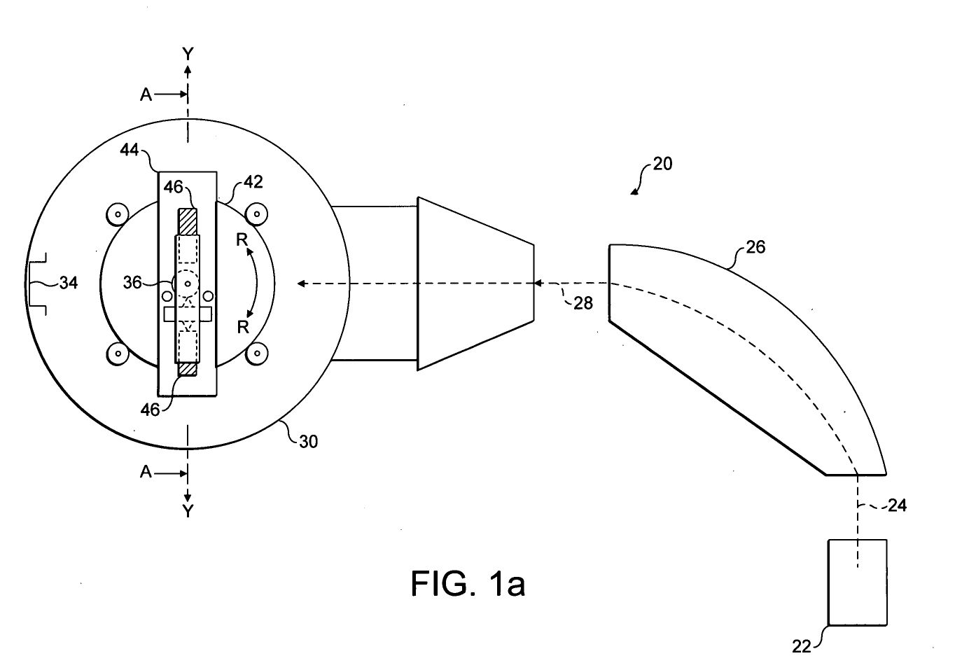

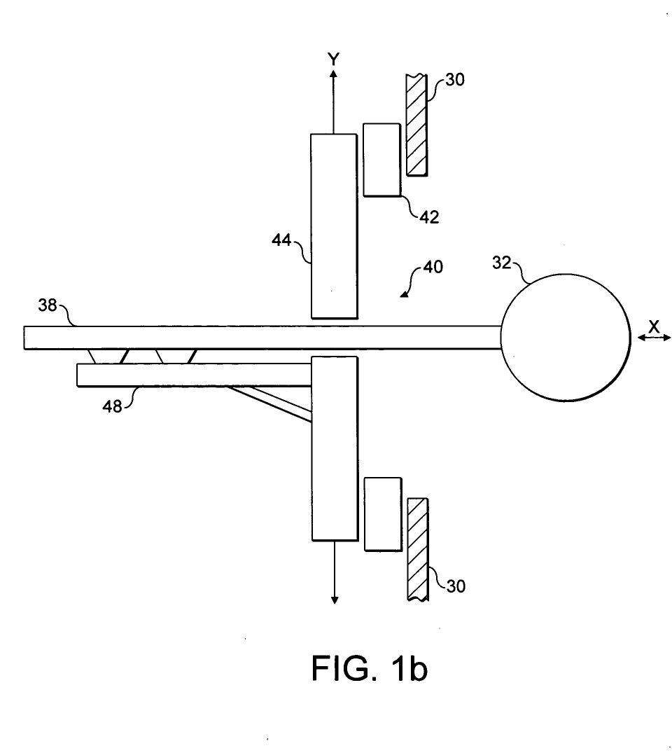

A schematic side view of an ion implanter 20 is shown in FIG. 1a and a part sectional view along the line AA of FIG. 1a is shown in FIG. 1b. The ion implanter 20 includes an ion source 22 which is arranged to generate an ion beam 24. The ion beam 24 is directed into a mass analyser 26 where ions of a desired mass/charge ratio are selected using a magnet. Such techniques are well known to those skilled in the art and will not be described further. It should be noted that, for convenience, the mass analyser 26 has been illustrated in FIG. 1a as bending the ion beam 24 from the ion source 22 in the plane of the paper, which is a vertical plane in the context of other parts of the illustrated ion implanter 20. In practice, the mass analyser 26 is usually arranged to bend this ion beam 24 in a horizontal plane.

The ion beam 28 exiting the mass analyser 26 may be subject to electrostatic acceleration or deceleration of the ions, depending upon the type of ions to be implanted and the desired implantation depth. Downstream of the mass analyser 26 is a vacuum chamber (hereinafter referred to as the process chamber 30) containing a wafer 32 to be implanted, as may be seen in FIG. 1b. In the present embodiment, the wafer 32 will be a single semiconductor wafer with a diameter typically of 200 mm or 300 mm. A beamstop 34 comprising a Faraday is located downstream of the wafer 32.

The ion beam 28 that exits the mass analyser 26 has a beam width and beam height substantially smaller than the diameter of the wafer 32 to be implanted. The scanning arrangement of FIGS. 1a and 1b (explained in more detail below) permits movement of the wafer 32 in multiple directions. This means that the ion beam 28 may be maintained along a fixed path relative to the process chamber 30 during implant.

The wafer 32 is mounted electrostatically upon a wafer holder or chuck 36 of a substrate support that also comprises an elongate support arm 38 to which the chuck 36 is connected. The support arm 38 extends out through the wall of the process chamber 30 in a direction generally perpendicular with the direction of the ion beam 28. The support arm 38 passes through a slot 40 (see FIG. 1b) in a rotor plate 42 which is mounted adjacent to a side wall of the process chamber 30. The end of the support arm 38 is mounted through a sledge 44. The support arm 38 is substantially fixed relative to the sledge 44 in the Y-direction as shown in FIGS. 1a and 1b. The sledge 44 is movable in a reciprocating manner relative to the rotor plate 42 in the direction Y shown in FIGS. 1a and 1b. This permits movement, also in a reciprocating manner, of the wafer 32 in the process chamber 30.

To effect mechanical scanning in the orthogonal, X-direction (that is, into and out of the plane of the paper in FIG. 1a and left to right in FIG. 1b), the support arm 38 is mounted within a support structure. The support structure comprises a pair of linear motors 46 that are spaced from the longitudinal axis of the support arm 38 above and below it as viewed in FIG. 1a. Preferably, the motors 46 are mounted around the longitudinal axis so as to cause the force to coincide with the centre of mass of the support structure. However, this is not essential and it will of course be understood that a single motor may instead be employed to reduce weight and/or cost.

The support structure also includes a slide 48 which is mounted in fixed relation to the sledge 44. Movement of the linear motors 46 along tracks (not shown in FIGS. 1a or 1b) disposed from left to right in FIG. 1b causes the support arm 38 likewise to reciprocate from left to right as viewed in FIG. 1b. The support arm 38 reciprocates relative to the slide 48 upon a series of bearings.

With this arrangement, the wafer 32 is movable in two orthogonal directions (X and Y) relative to the axis of the ion beam (Z) such that the whole wafer 32 can be passed across the fixed direction ion beam 28.

FIG. 1a shows the sledge 44 in a vertical position such that the surface of the wafer 32 is perpendicular to the axis of the incident ion beam 28. However, it may be desirable to implant ions into the wafer 32 at an angle to the ion beam 28. For this reason, the rotor plate 42 is rotatable about an axis defined through its centre, relative to the fixed wall of the process chamber 30. In other words, the rotor plate 42 is able to rotate in the direction of the arrows R shown in FIG. 1a thereby causing the wafer 32 to rotate in the same sense.

Further details of the above arrangement can be found in our co-pending U.S. patent application Ser. No. 10/119290, the contents of which are incorporated herein in their entirety.

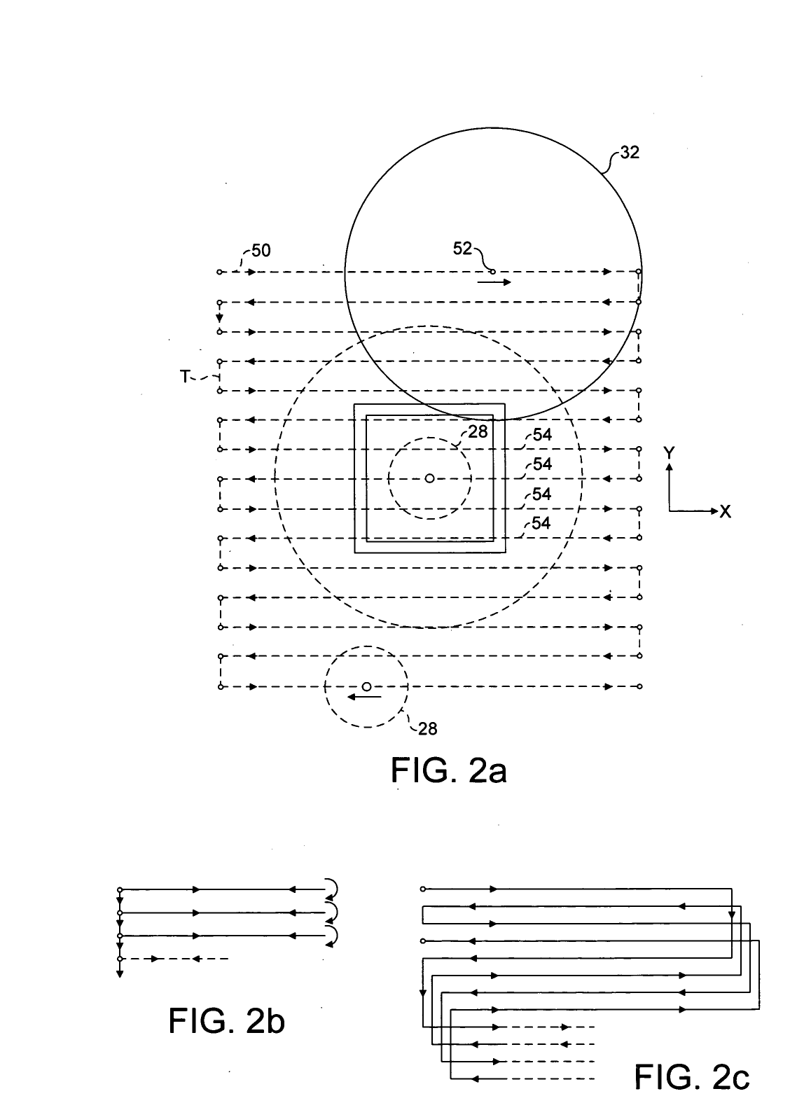

In a preferred arrangement, the chuck 36 is controlled to move according to a sequence of linear movements across the ion beam 28 in the X-coordinate direction, with each linear movement separated by a stepwise movement in the Y-coordinate direction. The resulting scan pattern is illustrated in FIG. 2a in which the dashed line 50 is the locus of the centre 52 of wafer 32 as it is reciprocated to and fro by the support arm 38 in the X-coordinate direction, and indexed downwardly in the Y-coordinate direction at the end of each stroke of reciprocation.

As can be seen, the reciprocating scanning action of the wafer 32 ensures that all parts of the wafer 32 are exposed to the ion beam 28. The movement of the wafer 32 causes the ion beam 28 to make repeated scans over the wafer 32 with the individual scan lines 54 being parallel and equally-spaced apart, until the ion beam 28 makes a full pass over the wafer 32. Although the line 50 in FIG. 2a represents the motion of the wafer 32 on the chuck 36 relative to the stationary ion beam 28, the line 50 is also a visualisation of the scans of the ion beam 28 across the wafer 32. Obviously, the motion of the ion beam 28 relative to the wafer 32 is in the reverse direction compared to the actual motion of the wafer 32 relative to the ion beam 28.

In the example shown in FIG. 2a, the controller scans the wafer 32 so that the ion beam 28 draws a raster of non-intersecting uniformly-spaced parallel lines 54 on the wafer 32. Each line 54 corresponds to a single scan of the ion beam 28 over the wafer 32. As illustrated, these ion beam scans extend beyond an edge of the wafer 32 to positions at which the beam cross-section is completely clear of the wafer 32 so that no beam flux is absorbed by the wafer 32 as the wafer 32 is moved into position for the next scan line 54.

Assuming the beam flux of atomic species to be implanted is constant over time, the dose of the desired species delivered to the wafer 32 is maintained constant over the wafer 32 in the X-coordinate direction of the scan lines 54 by maintaining a constant speed of movement of the wafer 32 in that direction. Also, by ensuring that the spacing between the scan lines 54 is uniform, the dose distribution along the Y-coordinate direction is also maintained substantially constant. In practice, however, there may be some progressive variation in the ion beam flux during the time taken for the wafer 32 to perform a complete pass over the ion beam 28, that is to complete one of the scan lines 54 illustrated in FIG. 2a.

In order to reduce the effect of such beam flux variations during a scan line 54, the beam flux may be measured periodically (as will be described in more detail below) and the speed at which the wafer 32 is moved over subsequent scan lines 54 adjusted accordingly. That is to say, the wafer 32 is driven along subsequent scan lines 54 at a slower speed if the beam flux decreases so as to maintain a desired rate of implant of the required atomic species per unit distance of travel, and vice versa. In this way, any variations in the ion beam flux during scan lines 54 leads to only minimal variation in the dose delivered to the wafer 32 in the scan line spacing direction.

In the scanning system described above with reference to FIG. 2a, the wafer 32 is translated by a uniform distance between reciprocating scan lines 54 to produce a zig-zag raster pattern. However, scanning could be controlled so that multiple scans are performed along the same scan line of the raster. For example, each raster line 54 could represent a double stroke or reciprocation of the wafer 32 along the scan line 54, with a uniformly-spaced translation in the Y-coordinate direction only between each double stroke. The resulting raster pattern is illustrated in FIG. 2b.

Furthermore, FIG. 2b illustrates only a single pass of the ion beam 28 over the wafer 32 in the Y-coordinate direction, but the complete implant procedure could include multiple passes. Then each such pass of the implant process could be arranged to draw a respective raster of uniformly-spaced scan lines 54. However, the scan lines 54 of multiple passes could be combined to draw a composite raster effectively drawn from the scans of a plurality of passes instead. For example, the scans of a second pass could be drawn precisely mid-way between the scans of the first pass to produce a composite raster having a uniform scan line spacing half the spacing between successive scans of each pass.

Staggering scan lines 54 across multiple passes can be beneficial in reducing the thermal load placed on the wafer 32 by the impinging ion beam 28. So, if a particular recipe requires a spacing of T in the scan lines 54 to achieve the desired dose, four passes could be made with each scan line in any particular pass being separated by 4T. Each of the passes is arranged to shift the phases of the scans of the pass spatially by the amount T, so that the composite raster drawn by the four passes has lines with pitch T as shown in FIG. 2c. In this way, the thermal loading of the wafer 32 is reduced whilst ensuring the raster line pitch is maintained at the desired spacing T.

In order to ensure adequate uniformity of dose delivered to the wafer 32 in the direction of the scan line spacing (along the Y-axis), this spacing or line pitch must be less than the cross-sectional dimension of the ion beam 28 in the same direction. This is because the ion flux is not uniform throughout the ion beam 28, but tends to increase from the beam edge to the centre. Overlapping adjacent scan lines 54 are used to overcome this lack of uniformity in the ion beam 28. The degree of overlap (and the number of passes) must be determined in accordance with the overall dosing requirement of the recipe.

Determining the optimum line spacing requires knowledge of the ion beam flux profile of the ion beam 28 along the Y-coordinate direction. This is because the spacing required to achieve uniformity to within a specified tolerance will vary according to this profile. Once the ion beam profile has been measured, Fourier transform analysis is used to determine the required line spacing. Further details of this procedure can be found in our co-pending U.S. patent application Ser. No. 10/251,780, the contents of which are incorporated herein in its entirety.

It may also be advantageous to measure the flux profile of the ion beam 28 in the X-coordinate direction. This allows the beam profile to be tuned to avoid certain problems, e.g. ion beam misalignment that may occur in the dispersion plane of the mass analysing magnet and cause the ion beam 28 to strike the wafer 32 at an incorrect angle of incidence or cause an offset during ion beam scanning. In addition, the beam profile in both X- and Y-coordinate directions may be tuned to avoid problems such as hot-spots in the ion beam 28 that may result in wafer 32 charging or to optimize the ion implantation process, e.g. to ensure an optimum beam size or optimum beam shape to achieve uniformity at the correct doping concentration over one of more scans. Obtaining beam profiles quickly allows rapid retuning of the ion beam to correct any problems.

Monitoring the angle of incidence of the ion beam 28 in both X- and Y-coordinate directions is also useful to ensure the desired implantation conditions are met. The path the ion beam 28 is following may be determined by measuring the ion beam profile at two locations spaced in the Z-coordinate direction as will be described in more detail below.

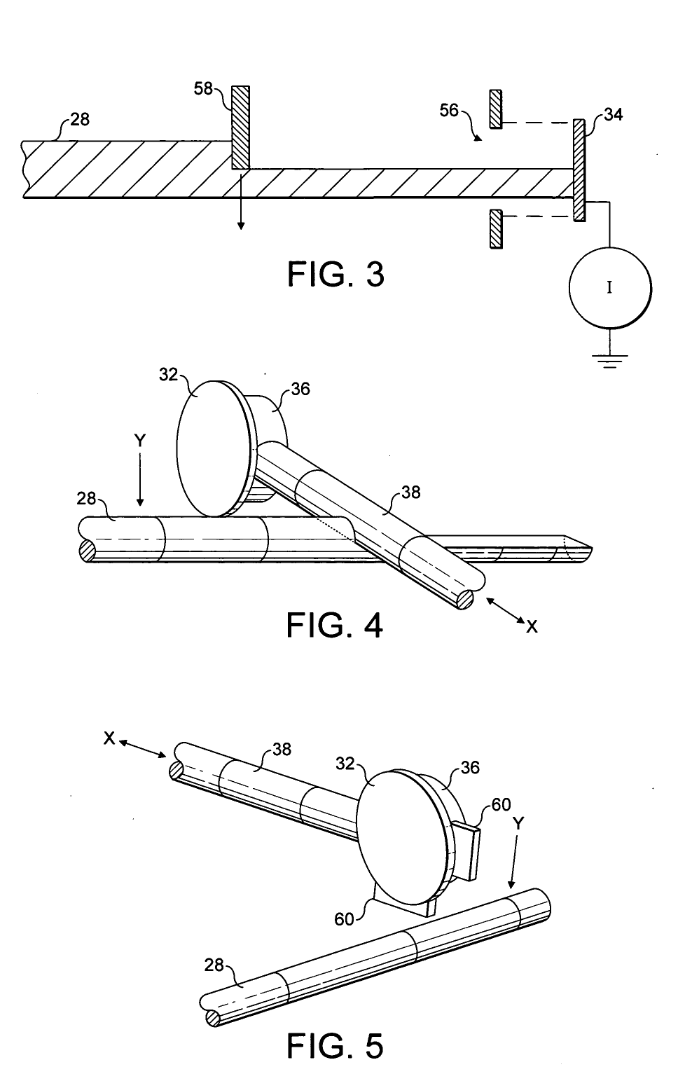

In a first set of embodiments of the present invention, the profile of the ion beam 28 is measured using the Faraday that acts as a beamstop 34. The Faraday 34 is a single detector that measure the ion beam current incident thereupon. The Faraday 34 has an entrance aperture 56 that is larger than the ion beam size and so can measure the current of the entire ion beam at an instant. In order to allow measurement of the flux profile across the ion beam 28, the ion beam 28 is progressively occluded by moving a shield 58 into the ion beam 28 or progressively uncovering the ion beam 28 by moving the shield 58 out of the ion beam 28. This can be performed in either the X- or Y-coordinate direction according to the profile being measured. Moving the shield 58 will lead to either a progressive increase or decrease in measured flux depending upon whether the shield 58 is being moved into or out of the ion beam 28. This arrangement is shown in FIG. 3. The change in measured flux between successive positions is indicative of the flux present in that part of the ion beam 28 just occluded or just uncovered. Implementing a scheme to extract this change in measured flux and determine the ion beam profile therefrom is straightforward in the art and requires no further description here.

Exemplary embodiments of substrate supports will now be described and their mode of operation will be explained with reference to progressive occlusion of the ion beam 28. The skilled person will appreciate that the following embodiments may work just as well when the ion beam 28 is progressively exposed such that the ion flux steadily increases.

It is convenient to use the substrate support to move the shield 58 as it already has the ability to move along the X- and Y-coordinate directions. A first embodiment is shown in FIG. 4 where the support arm 38 itself is used as a shield 58. In this embodiment, the support arm 38 has a flat lower edge that extends along the X-coordinate direction. Accordingly, the chuck 36 can be driven across the process chamber 30 past the ion beam 28 such that the flat lower edge of the support arm 38 is located above the ion beam 28. In this arrangement, passage of the ion beam 28 to the beamstop 34 is unobstructed and the Faraday 34 measures the total ion beam flux. The support arm 38 is then driven downwards into the ion beam 28 such that the flat lower edge progressively occludes the ion beam 28.

The ion beam 28 striking the support arm 38 will cause localised heating and also possibly ablation of material. In either event, the result is the possibility of contamination of a wafer 32 positioned on the chuck 36 by molecules and ions derived from the support arm 38. To this end, the portion of the support arm 38 used to occlude the ion beam is coated with semiconductor material so that the adverse effects of any sputtering are mitigated. The support arm 38 may be covered or coated with materials which either do not sputter readily or that will not cause contamination, such as graphite.

The effects of contamination of the wafer 32 may be further reduced by using the back of the support arm 38 to occlude the ion beam 28. In this way, the support arm 38 is rotated about 180° or so that the wafer 32 faces the beamstop 34 rather than the ion beam 28 and the back of the support arm 38 faces the ion beam 28, prior to driving the support arm 38 into the ion beam 28. of course, the back of the support arm 38 may be covered or coated with semi-conductor material or with graphite in this arrangement.

Alternatively, the side of the support arm 38 may be used to occlude the ion beam 28. This is advantageous as the wafer 32 faces neither the ion beam 23 nor the beamstop 34 when the ion beam is being occluded. This reduces further the chances of contaminating the wafer 32 as it alleviates the problem of back-sputtered material coming from the beamstop 34. As before, the side of the support arm 38 may be coated with semi-conductor material or graphite.

Movement of the substrate support is indexed and effected by a controller. This controller is used to move the support arm 38 through the ion beam 28. The reading from the Faraday 34 is acquired by the controller at a series of support arm positions that it of course knows. Accordingly, the controller builds up a data set of positions and ion beam flux values. If the support arm 38 is being driven into the ion beam 28, each successive flux will decrease by an amount corresponding to the flux received over the area occluded since the previous flux measurement. As each measurement corresponds to a complete slice across the ion beam 28, data collection can be performed far more quickly without sacrificing any count rate when compared with the prior art arrangement previously described where a 1 cm² Faraday aperture is used to measure the ion beam flux.

As the straight edge of the support arm 38 extends in the X-coordinate direction, the flux of slices taken in the X-coordinate direction are found. Hence the controller can be used to calculate and to plot ion beam flux against position thereby producing a flux profile in the Y-coordinate direction.

Advantageously, use of the support arm 38 to occlude the ion beam 28 ensures that the profile of the ion beam 28 at the location usually occupied by the wafer 32 during implantation. This is clearly a benefit when compared to using a dedicated shield 58 provided on its own drive mechanism, but that most likely will be located away from the implanting location to avoid interfering with operation of the substrate support.

If the height of the support arm 38 (its dimension in the Y-coordinate direction) is greater than the ion beam height, the profile may be collected in one pass of the support arm 38. However, a support arm 38 having a height less than the height of the ion beam 28, but greater than half the height of the ion beam 28, may be used. This is because the support arm 38 may be driven into the ion beam 28 first from above and then from below, allowing the two halves of the ion beam 28 to be measured in two passes. This is most easily achieved by providing the support arm 38 with upper and lower straight edges: a design with only a single straight edge may be used although this would require rotating the support arm 38 through 180° between the two passes (and perhaps covering or coating both front and back faces with semiconductor material or graphite as both faces will be exposed to the ion beam). If the support arm 38 has two straight edges, the profile may be collected in one pass. This is because the leading edge may collect the first half of the profile by progressive occlusion as the support arm 38 is driven into the ion beam 28 and the trailing edge may collect the second half of the profile by progressively uncovering the ion beam 28 as the support arm is driven out of the ion beam 28.

While the embodiment of FIG. 4 is particularly simple, it allows only the profile of the ion beam 28 in the Y-coordinate direction to be determined. A second embodiment is shown in FIG. 5 that allows the profile in both X- and Y-coordinate directions to be measured. The chuck 36 is modified to include straight edges 60 provided at its outermost and bottommost extremes such that they extend along the Y- and X-coordinate directions respectively. The edges 60 may be covered or coated with semiconductor material or graphite (or similar) to reduce contamination problems.

The edges 60 may be driven into the ion beam 28 from either side of the ion beam 28 or from above the ion beam 28 to cause progressive occlusion. As per the embodiment of FIG. 4, the controller records the change in measured ion flux along with the position of the chuck 36 and determines the ion flux profile therefrom. Driving the chuck 36 vertically will allow the profile in the Y-coordinate direction to be determined and driving the chuck 36 horizontally will allow the profile in the X-coordinate direction to be determined. The length of the straight edges 60 shown is greater than the extent of the ion beam 28 in the X- and Y-coordinate directions. The longer the straight edges 60 are, the less precise the requirement to centre the edges 60 on the ion beam 28 becomes to ensure that the straight edges 60 cut all the way cross the ion beam 28. However, the edges 60 need not be larger than the ion beam 28: in this case, a progressive change is still seen in the ion flux measurements irrespective of the fact that a zero measurement cannot be obtained. A disadvantage with this arrangement is that the difference between successive measurements reduces and so data acquisition times must be increased in order to obtain profiles at the same signal to noise ratio.

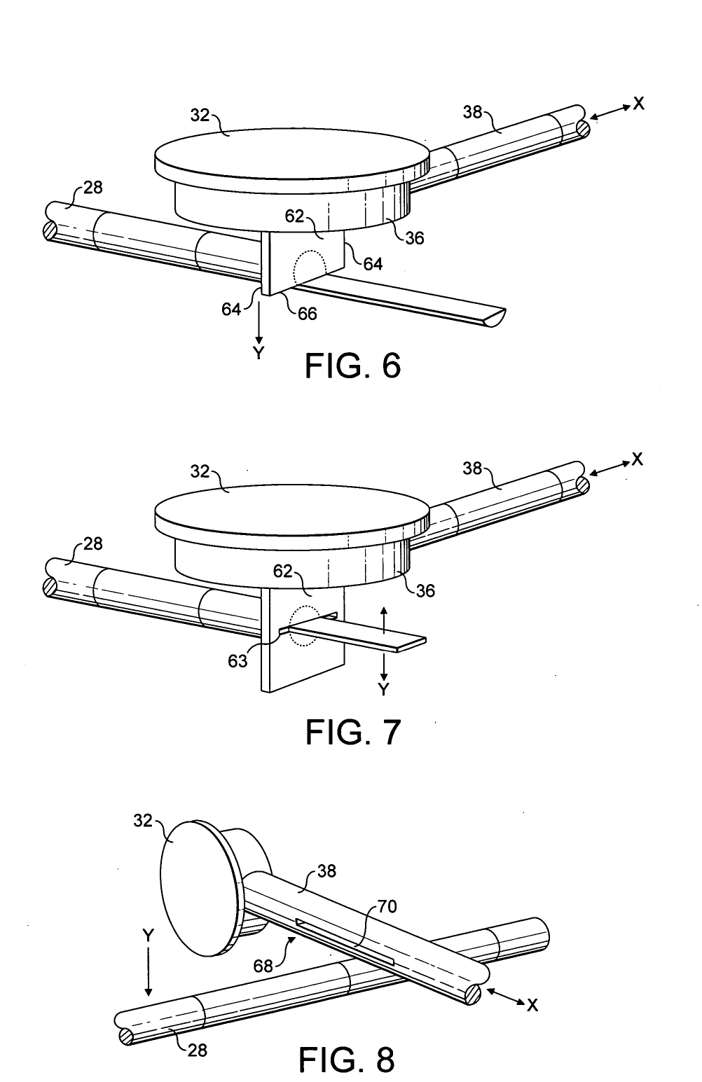

A further embodiment is shown in FIG. 6 that includes a shield 62 that extends from the back of the chuck 36, i.e. a square shield 62 is provided that is upstanding from the back face of the chuck 36. When the chuck 36 is rotated so that the wafer 32 faces away from both the ion beam 28 and beamstop 34 (to face either up or down), the square shield 62 presents two vertical edges 64 and a horizontal edge 66, any of which may be driven into the ion beam 28. Accordingly, the ion beam 28 may be progressively occluded in either the X- or Y-coordinate direction and the ion beam profile determined as above.

The shield 62 is covered or coated in a semiconductor material or graphite (or similar) to reduce the adverse effects of contamination. In fact, this embodiment is particularly beneficial in terms of avoiding contamination of a wafer 32. This is because the wafer 32 is rotated away from the ion beam 28 and the beamstop 34: the ion beam 28 striking the beamstop 34 can cause back-sputtering and hence contamination of a wafer 32 facing the beamstop 34.

Rather than occluding the ion beam by a progressively changing amount using a shield or edge provided on the substrate support, ion beam flux profiles may be collected using a shield 62 with a slot aperture 63 extending therethrough as shown in FIG. 7.

The slot aperture extends on the Y-coordinate direction and is wider than the full width of the ion beam 23. The shield 62 is sized to be bigger than the ion beam 23 such that all the ion beam 23 is occluded other than that portion passing through the slot 63. As per the embodiments of FIGS. 3 to 6, the shield 62 is driven through the ion beam 23 to vary the ion beam flux reaching the Faraday provided at the beamstop 34. At each position, the flux corresponding to a slice through the ion beam 23 is measured by the Faraday 34. Driving the substrate support in the Y-coordinate direction allows the ion beam flux of successive slices to be measured. Simply plotting the fluxes measured yields a flux profile in the Y-direction.

As will be appreciated, a similar slot 63 that extends in the Y-coordinate direction may be used to collect a flux profile along the X-coordinate direction. This second type of slot may be provided on a shield 62 either as an alternative to or in combination with the first type of slot 63. Slots 63 may be located in other positions, e.g. through the support arm, such as to corresponds to the appearance of FIG. 8.

A second set of embodiments will now be described in which one or more Faradays 68 provided on the substrate support of FIG. 1 are used to measure the ion beam flux. These embodiments are shown in FIGS. 8 to 10. In all instances, the Faradays 68 have slot apertures 70 extending across the full width or height of the ion beam 28 that allows ions to pass therethrough to be measured by an active detecting area than sits behind the apertures 70. The Faradays 68 provide a measure of the total flux along the line of the aperture 70, such that moving the Faradays 68 through the ion beam 28 allows a profile of the ion beam 28 to be determined. Of course, each of the measurements can be used directly when plotting the profile as opposed to the embodiments of FIGS. 3 to 6 where differences in successive measurements were required. As the apertures 70 extend across the full extent of the ion beam 28, count rates are far higher than for the much smaller 1 cm² Faraday used in the prior art previously described. This allows for faster data acquisition without sacrificing count rate. That said, the apertures 70 need not extend across the full width or height of the ion beam 28 as differences between successive measurements will still be recorded. However, such arrangements are not preferred due to the decrease in flux measurement that is inherent.

FIG. 8 shows a Faraday 68 provided on the support arm 38 with a slot aperture 70 that extends horizontally along the support arm 38, i.e. in the X-coordinate direction. Unlike the apertures 63 described with reference to FIG. 7, this aperture 70 does not extend all the way through the support arm 38. The support arm 38 may then be driven up or down into the ion beam 28 by the controller and the flux at each of a number of positions measured. The controller links these measurements to the position of the support arm 38 to provide the profile of the ion beam 28 in the Y-coordinate direction.

Advantageously, the profile of the ion beam 28 at the location the wafer 32 usually occupies during implantation is obtained. Providing a Faraday 68 on a dedicated drive arm would not produce as useful a profile because the drive arm would need to be offset from the wafer's implanting position to avoid interfering with operation of the substrate support.

The area of the support arm 38 surrounding the aperture 70 may be covered or coated in a semiconductor material or graphite (or similar) to reduce contamination problems.

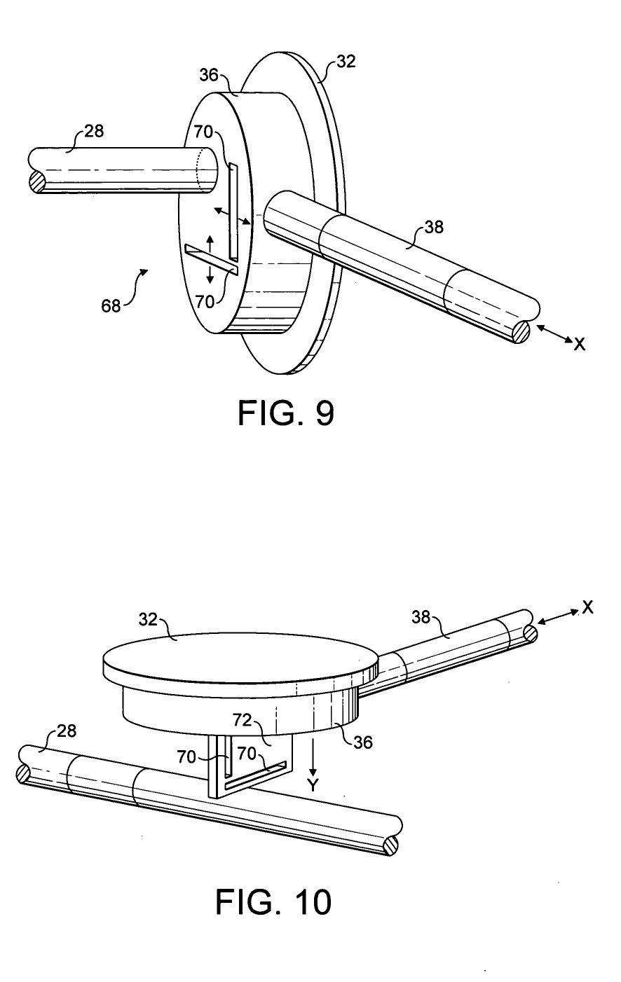

FIG. 9 shows a pair of Faradays 68 provided on the back face of the chuck 36. Each Faraday 68 is provided with a slot aperture 70, one extending in the X-coordinate direction, the other extending in the Y-coordinate direction. Driving the chuck 36 horizontally or vertically through the ion beam 28 with the support arm 38 rotated such that the wafer 32 faces the beamstop 34 allows the ion beam profile in both the X- and Y-coordinate directions to be determined. The back of the chuck 36 may be covered or coated with semiconductor material graphite (or similar) to reduce contamination problems.

FIG. 10 shows a further embodiment where the chuck 36 has a flat structure 72 projecting from its back face akin to the shield 62 of FIG. 6. The flat structure 72 of FIG. 10 is provided with a pair of Faradays 68. Each Faraday 68 is provided with a slot aperture 70, one extending in the X-coordinate direction, the other extending in the Y-coordinate direction. Driving the flat structure 72 horizontally or vertically through the ion beam 28 allows the ion beam profile in both the X- and Y-coordinate directions to be determined rapidly. The flat structure 72 may be covered or coated with semiconductor material or graphite (or similar) to reduce contamination problems. As with the embodiment of FIG. 6, this embodiment has the advantage that the wafer 32 faces neither the ion beam 28 nor the beamstop 34 thereby further minimising contamination problems.

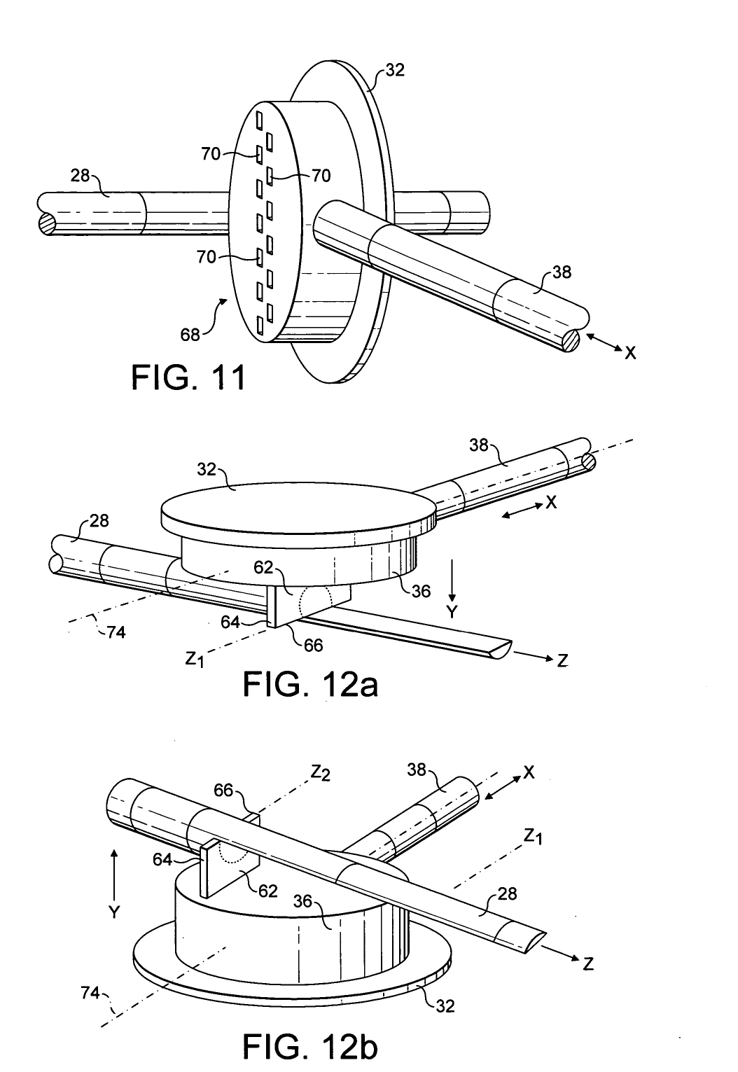

The embodiments of FIGS. 8 to 10 require the substrate support to be moved through the ion beam 28 progressively for a profile to be obtained. FIG. 11 shows a further embodiment that allows a complete profile to be obtained from a single position. An array of Faradays 68 are provided on the back of the chuck 36 to extend across the full height of the ion beam 28. The Faradays 68 are provided with short slot apertures 70. The apertures 70 extend to cover the full extent of the ion beam 28 by being arranged into two parallel lines to form a zig-zag pattern as shown in FIG. 10, such that the end of one aperture 70 is aligned with the start of the next aperture 70.

Placing the Faradays 68 at the centre of the ion beam 28 allows the profile of the ion beam 28 in the Y-coordinate direction to be captured in one instant. The profile in the X-coordinate direction can be acquired by driving the chuck 36 horizontally through the ion beam 28, and summing the measurements taken from the Faradays 68 at each position. Alternatively a second set of Faradays 68 could be provided that are arranged in an orthogonal direction. As before, the back of the chuck 36 may be coated in semiconductor material or graphite (or similar) to lessen the effects of contamination.

As mentioned previously, it is advantageous to be able to determine the exact path of the ion beam 28 around the implanting position. This is because it may diverge slightly from the envisaged ion beam path 28, and this may lead to incorrect angles of incidence with the wafer 32. A particularly simple method of finding the angle of incidence is to measure the ion beam flux profile at two or more positions along the Z-coordinate direction, and then use the centroid of the ion beam profiles to determine the ion beam path 28. In addition, measuring the ion beam flux profile reveals the extent of the ion beam 28, and so determination of any ion beam divergence or convergence along the Z-coordinate direction is also possible.

One way of measuring the ion beam flux profile along the Z axis is to provide two shields 58 or two slot Faradays 68, akin to those already described, at different positions along the Z axis. Two shields 58 may be used to occlude the ion beam 28 whilst measuring the ion beam flux with a Faraday provided at the beamstop 34. Both shields 58 or Faradays 68 could be provided on their own supports, mounted on a linear drive to allow translation in the X-coordinate direction. Alternatively, a single support could be mounted on a linear drive attached to a two-axis table. Thus would allow movement in and out of the ion beam 28 along X- and Y-coordinate directions, and would also allow a range of positions along the Z axis to be selected.

Where two separate shields 58 or Faradays 68 are used, the support structure could provide one of the shields 58 or Faradays 68 to be used in combination with a shield 58 or Faraday 68 provided on a separate structure, such as one of those previously described. Alternatively, a single shield 62 of the support arm 38 may be used to provide flux profiles at two positions along the Z axis will now be described.

FIGS. 12a and 12b show a modification of the arrangement of FIG. 6 that allows the ion beam profile in the Y-coordinate direction to be measured at two positions along the Z axis. The modification is to move the shield 62 away from the axis of rotation 74 of the support arm 38 towards one side of the chuck 36, as can be seen most clearly in FIG. 12b.

To measure the ion beam flux profile at a first position Z₁, the support arm 38 is moved such that the edge 66 of the shield 62 is located immediately above the ion beam 28. The support arm 38 is then moved down in the Y-coordinate direction so that the shield 62 progressively occludes the ion beam 28 and the flux profile in the Y-coordinate direction is obtained, as shown in FIG. 11a. The shield 62 and chuck 36 are then moved clear of the ion beam 28, and the support arm 38 is rotated through 180°. Rotation causes the offset shield 62 to move to a new position along the Z axis, Z₂. The support arm 38 is then moved up in the Y-coordinate direction so that the shield 62 progressively occludes the ion beam 28 and a second flux profile in the Y-coordinate direction is obtained, as shown in FIG. 12b.

In addition to obtaining ion beam flux profiles in the Y-coordinate direction, profiles may be obtained in the X-coordinate direction at the two positions Z₁ and Z₂. This is achieved by driving one of the two vertical edges 64 across the ion beam 28 in the X-coordinate direction at the Z₁ position, rotating the support arm 38 through 180° and then driving the shield 62 through the ion beam 28 in the X-coordinate direction at the Z₂ position.

Hence, ion beam flux profiles are obtained for two positions Z₁ and Z₂. The positions of Z₁ and Z₂ will be known from the geometry of the substrate support and, hence, the ion beam path 28 can be extrapolated from these profiles (assuming the ion beam 28 to follow a straight path, an acceptable approximation for the short distance of interest around the implanting position).

The embodiment of FIG. 5 may also be used in a similar manner. This is because the edges 60 are located towards the front face of the chuck 36 and so are offset from the axis of rotation 74 of the support arm 38. Accordingly, a 180° rotation of the support arm 38 will move the edges 60 along the Z-coordinate direction. The two edges 60 can be used to collect profiles in both X- and Y-coordinate directions.

The Faraday arrangement of FIG. 10 could be incorporated into the offset shield design just described. However, such a design would require Faradays 68 to be provided on the front and back of the shield 72 and account would need to be taken of unequal responsivity between front and back Faradays 68.

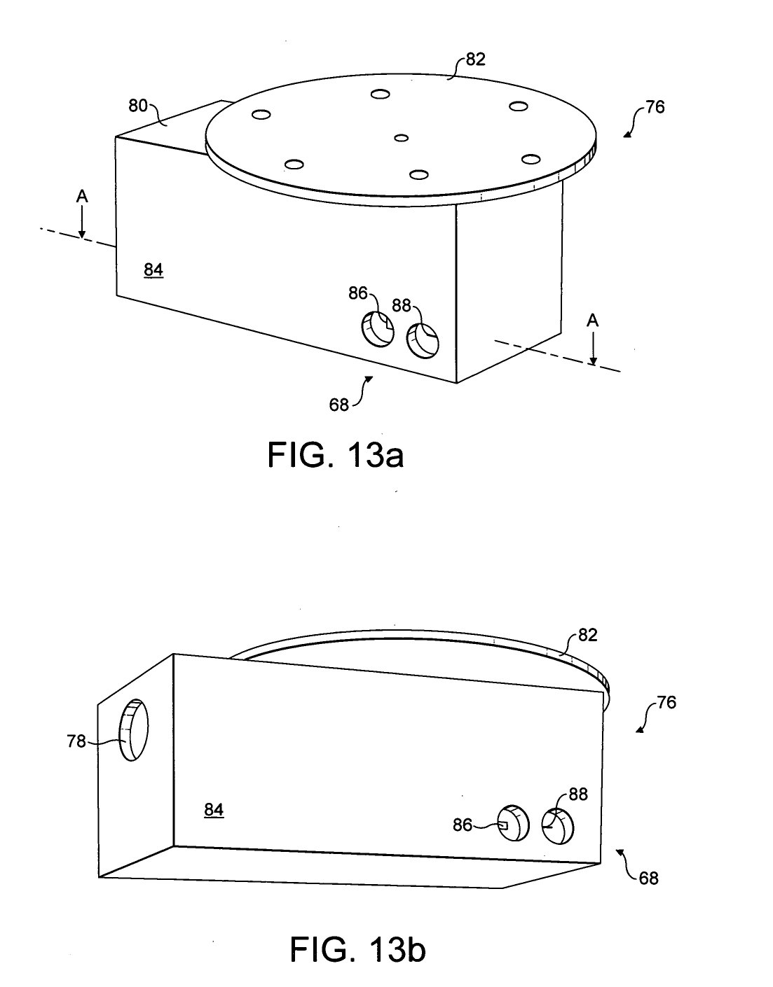

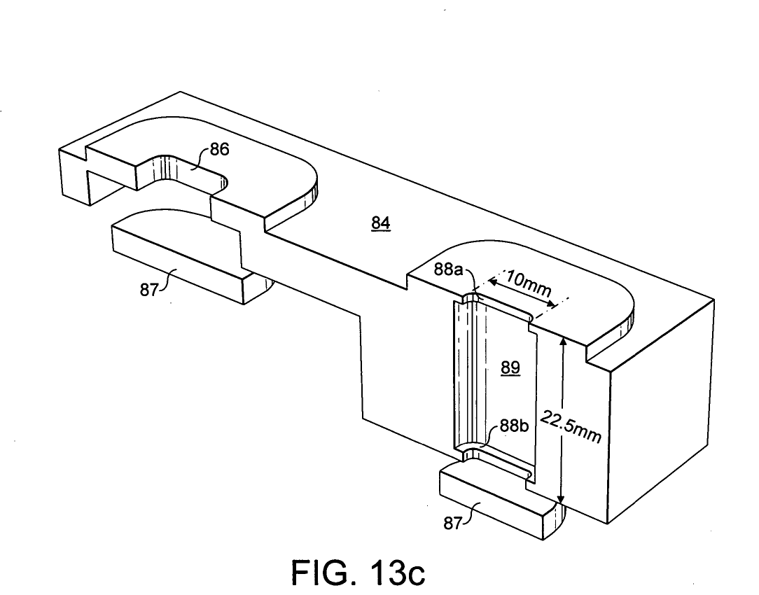

A further alternative design is shown in FIGS. 13a to 13c. These Figures show an end piece 76 for attachment to a support arm 38 via a coupling provided in a recess 78. The end piece 76 is block-shaped with a top face 80 that is provided with a circular chuck 82 for holding a wafer 32. A pair of Faradays 68 are provided behind the front face 84 of the end piece 78. One Faraday 68 corresponds to the prior art design in that it comprises a 1 cm² entrance aperture 86. An adjacent second Faraday 68 is provided behind a deep recess that is fronted by an upper slot aperture 88a. The slot 88 extends in the X-coordinate direction with dimensions of 10 mm×1 mm and so may be used to obtain ion beam flux profiles in the Y-coordinate direction as previously described.

The recess 89 has a depth of 22.5 mm and terminates with a second aperture 88b of corresponding shape, size and orientation. The active detecting area 87 of the Faraday 68 is located behind the lower aperture. The walls defining the recess 89 are electrically isolated from the active detecting area 87 to allow them to be grounded. The active detecting area 87 and lower aperture 88b form a Faraday 68 of the common design.

Hence, this Faraday 68 is fronted by a pair of apertures 88 that act to collimate the incident ion beam. This allows the ion beam angle to be measured (i.e. the angle of the exact ion beam path 28 away from the Z-axis). The deeply recessed Faraday 68 allows only ions entering substantially perpendicular to the front aperture 88a to travel through the rear aperture 88b and be detected at 87. Any off-axis ions will strike the internal wall and are most likely absorbed. Cutting back the walls between the apertures 88a,b minimises the chance that off-axis ions can be reflected onto the active detecting area 87 and spoil the measurement. The active detecting area 87 is magnetically suppressed to account for secondary electrons.

A combination of rotating the support arm 38 about its axis to change the acceptance angle of the slot aperture 88 and translation of the support arm 38 in X- and Y-coordinate directions to scan the slot aperture 88 across the entire ion beam 28 allows a detailed flux profile of the ion beam 28 to be determined. The deep slot aperture 88 can be used with any of the slot Faradays 68 previously described.

As will be appreciated by the skilled person, variations may be made to the above embodiments without departing from the scope of the present invention.

For example, all of the above embodiments relate to operation of the ion implanter 20 of FIG. 1 where the ion beam 28 travels along a fixed ion beam path and wherein the chuck 36 moves in a raster pattern in order to allow the ion beam 28 to be scanned across the wafer 32. However, this need not be the case as the above embodiments could be used in an ion implanter 20 where the ion beam 28 is scanned rather than the chuck 36. Accordingly, when the ion beam profile is being measured, the chuck 36 could be positioned within the process chamber 30 within range of the ion beam 28, and the ion beam 28 could then be scanned over an edge 60, 64, 66 or aperture 70 of a Faraday 68 using electrostatic or magnetic deflection for example. Ion implanters 20 that work in this way have deflector plates or magnets for deflecting the ion beam 28 that operate in the X- and Y-coordinate directions and so the alignment of edges 60, 64, 66 and aperture 70 shown in FIGS. 4 to 10 would be appropriate. Whilst deflecting the ion beam 28 is possible, it is not preferred as the deflection process may cause changes in the profile of the ion beam as a whole.

The above embodiments may be used as alternatives or may even be used in combination. For example, a straight edge 60, 64, 66 in the X-coordinate direction may be combined with a slot aperture 63 or Faraday aperture 70 extending in the Y-coordinate direction. Moreover, complimentary features may be included such that a substrate support comprises both an edge 60, 64, 66 and a slot 63 or Faraday 70 aperture extending in the X-coordinate direction. Such an arrangement would provide a degree of redundancy.

Clearly, the skilled person can make a choice between whether to measure the ion beam profile in the X- or Y-coordinate direction or even to measure the ion beam profile in both directions. This will be dictated largely by the needs of the particular application.

Whilst the above embodiments have been described from the context of driving an edge 60, 64, 66, slot aperture 63 or Faraday aperture 70 into the ion beam 28, it is of course straightforward to reverse the situation and have the edge 60, 64, 66, slot aperture 63 or Faraday aperture 70 being driven out of the ion beam 28.

The above embodiments describe measuring the ion beam profile by recording one dimensional profiles which effectively integrate the flux intensity along a straight line, either in the X-coordinate or Y-coordinate direction. This relies on the use of straight edges 60, 64, 66 or a straight slot aperture 63/70. However, whilst this is the optimum arrangement, variations can be made such that straight edges 60, 64, 66 or straight apertures 70 are used that are not exactly aligned with the X-or Y-coordinate directions. Furthermore, edges and Faraday apertures that are not straight could also be used. In addition, straight edges 60, 64, 66 and apertures 70 need not be arranged orthogonal to the directions of motion, but may be disposed at other angles.

The use of a controller to effect movement of the chuck 36 and to acquire data from the Faraday detector 34, 68 or detectors 68 is but merely one implementation of the present invention. Alternative implementations include using the controller to supply the positional information of the chuck 36 to a further computing means that also collects information relating to the measured ion flux. In addition, the calculations required to relate differences in ion flux measurements and generate an ion beam profile may be implemented in hardware or software.

1. A method of measuring an ion beam flux profile in an ion implanter operable to generate an ion beam along an ion beam path for implanting in a substrate held at a target position by a substrate support, the ion implanter comprising an ion beam flux detector located downstream of the target position and a shield provided by the substrate support for shielding the detector from the ion beam when the shield is located in the ion beam path, the method comprising the steps of:
(a) causing a-first relative motion between the substrate support and the ion beam such that the shield. occludes the ion beam by a progressively changing amount;
(b) measuring the ion beam flux with the detector during said first relative motion; and
(c) determining the ion beam flux profile in a first direction by using changes in the measured ion beam flux.

2. A method according to claim 1, wherein the ion implanter comprises a further said shield provided by the substrate support and the method further comprises the steps of:
causing a second relative motion between the substrate support and the ion beam such that the further shield occludes the ion beam by a progressively changing amount;
measuring the ion beam flux with the detector during said second relative motion; and
determining the ion beam flux profile in a second direction by using changes in the measured ion beam flux.

3. A method according to claim 2 wherein the first and second directions are substantially orthogonal.

4. A method according to claim 1, comprising the step of moving the substrate support relative to a fixed ion beam to cause the first relative motion.

5. A method according to claim 2, comprising the step of moving the substrate support relative to a fixed ion beam to cause the first relative motion and the second relative motion.

6. A method according to claim 1, further comprising the step of rotating the substrate holder to ensure that the substrate substantially faces the detector prior to causing the relative motion between substrate holder and ion beam that progressively occludes the beam.

7. A method according to claim 1, further comprising the step of rotating the substrate holder to ensure that the substrate faces away from both the detector and the direction of incidence of the ion beam prior to causing the relative motion between substrate holder and ion beam that occludes the beam.

8. A method according to claim 1, wherein the substrate support comprises an arm and the method comprises causing the relative motion between the substrate support and the ion beam such that the arm occludes the ion beam.

9. A method according to claim 1, wherein the substrate support comprises a chuck with an edge and the method comprises causing the relative motion between the substrate support and the ion beam such that the edge occludes the ion beam.

10. A method of measuring an ion beam path including the method of claim 1, comprising: performing steps (a) and (b) at a first position along the assumed ion beam path and step (c) to determine a first ion beam flux profile at the first position; repeating steps (a) and (b) at a second position spaced along the assumed ion beam path from the first position and step (c) to determine a second ion beam flux profile at the second position; identifying a common feature in the first and second flux profiles; determining the positions of the common feature in the first and second flux profiles; and inferring the ion beam path from the positions so determined.

11. A method of measuring an ion beam path including the method of claim 9, comprising: performing steps (a) and (b) at a first position along the assumed ion beam path and step (c) to determine a first ion beam flux profile at the first position; repeating steps (a) and (b) at a second position spaced along the assumed ion beam path from the first position and step (c) to determine a second ion beam flux profile at the second position; identifying a common feature in the first and second flux profiles; determining the positions of the common feature in the first and second flux profiles; and inferring the ion beam path from the positions so determined, and wherein the edge is located eccentrically with respect to an axis of the substrate support and the method comprises rotating the substrate support to move the edge from the first position to the second position.

12. A method of measuring an ion beam flux profile in an ion implanter operable to generate an ion beam along an ion beam path for implanting in a substrate held at a target position by a substrate support, the ion implanter comprising an ion beam flux detector located downstream of the target position and a slot aperture provided in the substrate support for letting only a portion of the ion beam propagate to the detector when the aperture is located in the ion beam path, the method comprising the steps of:
(a) causing a first relative motion between the substrate support and the ion beam such that the ion beam scans across the aperture;
(b) using the detector to take measurements of the ion beam flux during the first relative motion through the ion beam; and
(c) determining an ion beam flux profile from the ion beam flux measurements.

13. A method according to claim 12, wherein the slot aperture is elongate and a further elongate slot aperture is provided in the substrate support, the method further comprising: causing a second relative motion between the substrate support and the ion beam such that the ion beam scans across the further aperture; using the detector to take further measurements of the ion beam flux during the second relative motion through the ion beam; and determining a second ion beam flux from the further ion beam flux measurements.

14. A method of measuring an ion beam flux profile in an ion implanter operable to generate an ion beam along an ion beam path for implanting in a substrate held at a target position by a substrate support, the substrate support providing a first elongate slot ion beam flux detector, the method comprising the steps of:
(a) causing a first relative motion between the substrate support and the ion beam such that the ion beam scans across the first detector;
(b) using the first detector to take measurements of the ion beam flux during the first relative motion through the ion beam; and
(c) determining a first ion beam flux profile from the ion beam flux measurements.

15. A method according to claim 14, wherein the ion implanter comprises a second elongate slot ion beam flux. detector and the method further comprises:
causing a second relative motion between the substrate support and the ion beam such that the ion beam scans across the second detector;
using the second detector to take further measurements of the ion beam flux during the second relative motion through the ion beam; and
determining a second ion beam flux profile from the further ion beam flux measurements.

16. A method according to claim 15, wherein the first and second profiles are along substantially orthogonal directions.

17. A method according to claim 12, wherein the method comprises moving the substrate support relative to a fixed ion beam thereby causing the first relative motion.

18. A method according to claim 14, wherein the method comprises moving the substrate support relative to a fixed ion beam thereby causing the first relative motion and the second relative motion.

19. A method of measuring an ion beam path including the method of claim 12 or claim 14, comprising: performing steps (a) and (b) at a first position along the assumed ion beam path and step (c) to determined a first ion beam flux profile at the first position; reporting steps (a) and (b) at a second position spaced along the assumed ion beam path from the first position and step (c) to determine a second ion beam flux profile at the second position; identifying a common feature in the first and second flux profiles; determining the positions of the common feature in the first and second flux profiles; and inferring the ion beam path from the positions so determined.

20. A method of measuring the path of an ion beam comprising:
(a) measuring a first ion beam flux profile at a first position along the assumed path of the ion beam;
(b) measuring a second ion beam flux profile at a second position spaced along the assumed path of the ion beam from the first position;
(c) identifying a common feature in the first and second flux profiles;
(d) determining the position of the common feature in the first and second flux profiles; and
(e) inferring the path of the ion beam path from the positions in step (d).

21. A method according to claim 20, wherein steps (a) and (b) comprise measuring flux profiles using at least one elongate slot ion beam flux detector locatable at the first and second positions.

22. An ion beam monitoring arrangement for use in an ion implanter operable to generate an ion beam along an ion beam path for implanting in a substrate held at a target position, the ion beam monitoring arrangement comprising:
a substrate support arranged to hold the substrate at the target position;
a detector located in the ion beam path downstream of the target position and operable to take measurements of the ion beam flux incident on the detector;
a shield provided by the substrate support in a position to occlude the ion beam from the detector by a progressively changing amount during a first relative motion between the substrate support and the ion beam; and
processing means operable to determine an ion beam flux profile in a first direction by using changes in the ion beam flux measurements.

23. An ion beam monitoring arrangement according to claim 22, wherein a further said shield is provided by the substrate support in a position to occlude the ion beam from the detector by a progressively changing amount during a second relative motion between the substrate support and the ion beam, the detector is operable to take further measurements of the ion beam flux incident on the detector, and the processing means is operable to determine an ion beam flux profile in a second direction by using changes in the further ion beam flux measurements.

24. An ion beam monitoring arrangement according to claim 23, wherein the first and second directions are substantially orthogonal.

25. An ion beam monitoring arrangement according to claim 22, wherein the substrate support is moveable relative to a fixed ion beam to cause the first relative motion.

26. An ion beam monitoring arrangement according to claim 23, wherein the substrate support is moveable relative to a fixed ion beam to cause the first relative motion and the second relative motion.

27. An ion beam monitoring arrangement according to claim 22, wherein the substrate support comprises an arm with an edge arranged to occlude the ion beam during the relative motion.

28. An ion beam monitoring arrangement according to claim 22, wherein the substrate holder comprises a chuck with a first edge arranged to the ion beam during the first relative motion.

29. An ion beam monitoring arrangement according to claim 28, wherein the first edge is straight and extends substantially perpendicular to the direction of the first relative motion.

30. An ion beam monitoring arrangement according to claim 28, wherein the substrate support is rotatable about its longitudinal axis and the shield is located on the chuck to be eccentric with respect to the longitudinal axis.

31. An ion beam monitoring arrangement according to claim 23, wherein the substrate holder comprises a chuck with a first edge arranged to occlude the ion beam during the first relative motion and a second edge arranged to occlude the ion beam during the second relative motion, the second edge being disposed substantially orthogonally to the first edge.

32. An ion beam monitoring arrangement according to claim 22, wherein the substrate holder comprises a chuck with a first face for receiving a substrate and a second, opposed face having the shield projecting therefrom.

33. An ion beam monitoring arrangement according to claim 21, wherein the substrate holder comprises a chuck with a first face for receiving a substrate and a second, opposed face having the shield projecting therefrom and wherein the shield comprises two peripheral edges disposed in substantially orthogonal arrangement such that one edge occludes the ion beam during the first relative motion and the second edge occludes the ion beam during the second relative motion.

34. An ion beam monitoring arrangement according to claim 32, wherein the substrate support is rotatable about its longitudinal axis and the shield is located on the chuck to be eccentric with respect to the longitudinal axis.

35. An ion beam monitoring arrangement according to claim 22, wherein the substrate support is a single wafer substrate support.

36. An ion beam monitoring arrangement for use in an ion implanter operable to generate an ion beam along an ion beam path for implanting in a substrate held at a target position, the ion beam monitoring arrangement comprising:
a substrate support arranged to hold the substrate at the target position;
a detector located in the ion beam path downstream of the target position and operable to take measurements of the ion beam flux incident thereon;
a slot aperture provided in the substrate support in a position to allow portions of the ion beam to propagate to the detector during a first relative motion between the substrate support and the ion beam; and
processing means operable to determine a first ion beam flux profile from the ion beam flux measurements.

37. An ion beam monitoring arrangement according to claim 36, wherein the slot aperture is elongate with the direction of elongation being substantially orthogonal to the direction of the first relative motion.

38. An ion beam monitoring arrangement according to claim 36, further comprising a second elongate slot aperture in the substrate support in a position to allow portions of the ion beam to propagate to the detector during a second relative motion between the substrate support and the ion beam, and wherein the processing means is operable to determine a second ion beam flux profile from further ion beam flux measurements taken by the detector during the second relative motion.

39. An ion beam monitoring arrangement according to claim 38, wherein the directions of the first and second relative motions are substantially orthogonal.

40. An ion beam monitoring arrangement according to claim 38, wherein the substrate support comprises a support arm and the slot aperture is provided through the support arm.

41. An ion beam monitoring arrangement according to claim 36, wherein the substrate support comprises a chuck for receiving the substrate and slot aperture is provided through the chuck.

42. An ion beam monitoring arrangement according to claim 36, wherein the substrate support comprises a chuck for receiving the substrate on a first face thereof and a second, opposed face from which an upstanding element projects, the slot aperture being provided through the upstanding element.

43. An ion beam monitoring arrangement according to claim 36, wherein the substrate support is moveable relative to a fixed ion beam to cause the first relative motion.

44. An ion beam monitoring arrangement according to claim 38, wherein the substrate support is moveable relative to a fixed ion beam to cause the first relative motion and the second relative motion.

45. An ion beam monitoring arrangement for use in an ion implanter operable to generate an ion beam along an ion beam path for implanting in a substrate held at a target position, the ion beam monitoring arrangement comprising:
a substrate support arranged to hold the substrate at the target position;
a first elongate slot ion beam flux detector provided by the substrate support operable to take measurements of the ion beam flux incident thereon during a first relative motion between the substrate support and the ion beam; and
processing means operable to determine a first ion beam flux profile from the ion beam flux measurements.

46. An ion beam monitoring arrangement according to claim 45, wherein the first detector comprises an elongate aperture or an elongate detecting element, and the direction of elongation is substantially orthogonal to the direction of the first relative motion.

47. An ion beam monitoring arrangement according to claim 45, further comprising a second said elongate slot ion beam flux detector operable to take further measurements of the ion beam flux incident thereon during a second relative motion between the substrate support and the ion beam and wherein the processing means is operable to determine a second ion beam flux profile from the further ion beam flux measurements.

48. An ion beam monitoring arrangement according to claim 47, wherein the directions of the first and second relative motions are substantially orthogonal.

49. An ion beam monitoring arrangement according to claim 45, wherein the first detector comprises a Faraday with an elongate entrance aperture.

50. An ion beam monitoring arrangement according to claim 47, wherein the first detector comprises a Faraday with an elongate entrance aperture and the second detector comprises a Faraday with an elongate entrance aperture.

51. An ion beam monitoring arrangement according to claim 45, wherein the substrate support further comprises a support arm and the first detector and any second detector are provided on the arm.

52. An ion beam monitoring arrangement according to claim 45, wherein the substrate support further comprises a chuck for receiving the substrate on a first face thereof and wherein the first detector and any second detector are provided on a second, opposed face of the chuck.

53. An ion beam monitoring arrangement according to claim 45, wherein the substrate support further comprises a chuck for receiving the substrate on a first face thereof and a second, opposed face from which an upstanding element projects, the first detector and any second detector being provided on the upstanding element.

54. An ion beam monitoring arrangement according to claim 45, wherein the substrate support is moveable relative to a fixed ion beam to cause the first relative motion.

55. An ion beam monitoring arrangement according to claim 47, wherein the substrate support is moveable relative to a fixed ion beam to cause the first relative motion and the second relative motion.

56. An ion beam monitoring arrangement according to claim 45, wherein the first detector comprises a recessed detecting element located behind a deep recess.

57. An ion beam arrangement according to claim 56, wherein the recess is fronted by an elongate aperture having a first short dimension and a second long dimension, and wherein the depth of the recess is at least five times as great as the short dimension.

58. An ion beam arrangement according to claim 57, wherein the depth of the recess is at least ten times as great as the short dimension.

59. An ion beam arrangement according to claim 57, wherein the depth of the recess is at least twenty times as great as the short dimension.

60. An ion beam monitoring arrangement according to claim 45, wherein the first detector comprises an elongate array of discrete detecting elements operable to take measurements of the ion beam flux incident thereon during the first relative motion, and the processing means are operable to determine an ion beam flux profile by summing concurrent ion beam flux measurements taken by detecting elements within the array and to determine a further ion beam flux profile from the ion beam flux measurements taken by a detecting element.

61. An ion beam monitoring arrangement according to claim 60, wherein the detecting elements are disposed in two adjacent parallel lines in an alternating zig-zag pattern.

62. An ion beam monitoring arrangement according to claim 45, wherein the substrate support is a single wafer substrate support.

63. An ion beam monitoring arrangement for use in an ion implanter operable to gene-rate an ion beam along an ion beam path for implanting in a substrate, the ion beam monitoring arrangement comprising
(a) first measurement means operable to measure a first ion beam flux profile at a first position along the assumed path of the ion beam;
(b) second measurement means operable to measure a second ion beam profile at a second position spaced along the assumed path of the ion beam from the first position; and
(c) processing means operable to identify a common feature in the first and second flux profiles, to determine the positions of the common feature in the first and second flux profiles and to infer the ion beam path from the position so determined.

64. An ion beam monitoring arrangement according to claim 63, wherein a single measurement means provides both the first and second measurement means.

65. An ion beam monitoring arrangement according to claim 63, wherein the first and/or second measurement means comprises a shield operable to occlude the ion beam by a progressively changing amount and a detector located downstream from the shield in the ion beam.

66. An ion beam monitoring arrangement according to claim 63, wherein the first and/or second measurement means comprises an elongate slot ion beam flux detector.

67. An ion implanter process chamber including the ion beam monitoring arrangement of any of claims 22, 36, 45 or 63.

68. An ion implanter including the ion beam monitoring arrangement of any of claims 22, 36, 45 or 63.
